(19) United States
(12) Patent Application Publication
(10) Pub. No.: US 2002/0093345 A1
(43) Pub. Date: Jul. 18, 2002

(54) Zero to 100% water in liquid hydrocarbon flow meter

(75) Inventor: Bijan K. Amini, Houston, TX (US)

Correspondence Address: LAW OFFICES OF DAVID MCEWING, 4582 KINGWOOD DRIVE, BOX 118, KINGWOOD, TX, 77345, US

(73) Assignee: EM-Tech LLC

(21) Appl. No.: 09/734,540

(22) Filed: Dec. 11, 2000

Related U.S. Application Data
(60) Provisional application No. 60/170,174, filed on Dec. 10, 1999.

(51) Int. Cl. G01R 27/26

(52) U.S. Cl. 324/667

(57) ABSTRACT

There are many liquid flows in which the concentration and content of the materials within the flow change or vary. One important example is the varying percentage of water found in a liquid hydrocarbon, e.g., crude oil. It is desired to detect and measure the variations in the concentration of water contained in a hydrocarbon being removed from a hydrocarbon production well. It is also important to detect changes in the salinity of the water and to production well.

The invention subject of this application teaches a method and apparatus to accurately measure concentration and composition of material within a liquid. Specifically, the invention can detect and measure the concentration of water contained in a hydrocarbon flow. The invention can also detect and measure the salinity of the water. It can also be used to determine or distinguish the type of the hydrocarbon in a flow.

### CROSS REFERENCE TO RELATED APPLICATION

The present invention claims benefit of U.S. Provisional Application No. 60/166,696, entitled “Zero to 100% Water in Liquid Hydrocarbon Flow Meter,” filed Dec. 10, 1999.

### BACKGROUND OF THE INVENTION

1. Field of the Invention

There are many flows in which the concentration and content of the materials within the flow change or vary. One important example is the varying percentage of water found in a liquid hydrocarbon, e.g., crude oil. It is desired to detect and measure the concentration or changes in concentration of water contained in a hydrocarbon. It is also important to detect and measure the concentration and changes in the concentration of dissolved ionic compounds within the water, i.e., water salinity. It is also important to measure the dielectric of the hydrocarbon. From measurements of the dielectric properties of the hydrocarbon, the density of the hydrocarbon content of the flow can be ascertained.

The invention subject of this application teaches a method and apparatus to accurately measure the concentration and composition of material within a liquid. Specifically, the invention can detect and measure the concentration of water contained in a hydrocarbon flow. The invention can also detect and measure the salinity of the water within such flow. It can also be used to determine or distinguish the type of the hydrocarbon in a flow.

2 Description of Related Art

It has not been possible to accurately measure the water content of many liquid mixtures. Methods or apparatus that are suitable for measuring water at low concentrations are inaccurate or inoperable at higher water concentrations. Also, the prior methods were not accurate or operable when the water was not homogeneously mixed within the liquid. High concentrations of dissolved ionic compounds in the water also hampered the measurements. Other methods used devices that intruded into the conduit or pipe, thereby hampering the flow of the hydrocarbon or were subject to breakdown or wear.

### SUMMARY OF THE INVENTION

The invention subject of this application teaches a method and apparatus to accurately measure the concentration and composition of magnetically permeable or electrically conductive material within a liquid. Specifically, the invention can detect and measure the concentration and changes in water concentration contained within a hydrocarbon flow stream. Such a flow stream can include but is not limited to crude oil. The invention can also detect and measure the salinity of the water within such flow. The invention can also be used to determine or distinguish the type of the hydrocarbon in a flow. The invention teaches the use of alternate methods or apparatus depending upon the concentration of the water in the liquid. For example, in a hydrocarbon mixture containing a low water concentration, an electrical field may be used to determine the percentage of water in hydrocarbon. However, at higher water concentrations, it may be preferred to utilize a magnetic field. This can be attributed to the increased electrical conductivity of the mixture containing the higher concentration of water.

It is well known that water can be highly electrically conductive, depending in part upon the content of dissolved compounds. Water also has a magnetic dipole moment. Hydrocarbon has relatively low electrical conductivity, but also possesses a magnetic dipole moment. It is desired to detect and measure the variations in the concentration of water contained in a hydrocarbon being removed from a hydrocarbon production well, hydrocarbon reservoir, storage tank, pipeline, etc. It is also important to detect changes in the salinity of the water and to measure changes in the hydrocarbon flow stream and to identify the hydrocarbon within the flow stream.

In some embodiments of the invention, differing methods or components are utilized for the desired detection and measurement, depending upon the concentration of water or concentration of dissolved ionic compounds (hereinafter “salinity”) within the water. Specifically, as the percentage of water increases, changing the method of measurement may provide greater accuracy. For example, in a solution containing a low water concentration, measurement of the electrical capacitance may be used to determine the percentage of water in solution. However, at higher water concentrations, it is preferable to utilize an oscillating magnetic flux. This can be attributed to the increased electrical conductivity of the hydrocarbon mixture containing higher concentrations of water or increased water salinity.

The method and apparatus of the present invention allows for the detection and measurement of at least the following properties of the subject liquid.

1. The concentration of water within the liquid.

2. Salinity of water, i.e., concentration of dissolved ionic compounds or solute within the water.

3. The dielectric of the liquid.

It will be appreciated that the measured dielectric of a hydrocarbon mixture can provide useful information regarding the hydrocarbon density and therefore the molecular weight of the constituent hydrocarbons.

It is therefore a goal of this invention to provide a method for measuring the concentration of water in a liquid. It is a further goal of the invention to provide a method of determining the salinity of the water. It is yet another goal of the invention to provide a method and apparatus for determining the dielectric of the liquid.

It is yet a further goal of the invention to provide a method and apparatus for measuring the properties of water concentration and salinity when the liquid contains substantial concentration of hydrocarbon. It is also a goal to provide a method and apparatus for determining the dielectric properties of hydrocarbon within the liquid. It is yet another goal to provide a method and apparatus for measuring the properties of water concentration, salinity, and hydrocarbon dielectrics over a range of liquids containing zero to 100% water.

### BRIEF DESCRIPTION OF THE DRAWINGS

The accompanying drawings, which are incorporated in and constitute a part of the specification, illustrate preferred embodiments of the invention. These drawing, together with the general description of the invention given above and the detailed description of the preferred embodiments given below, serve to explain the principles of the invention.

FIG. 1 illustrates a plot of measured amplitude of oscillating magnetic flux received through a liquid such as water at varying frequencies.

FIG. 2 illustrates a plot of the measured amplitude of oscillating magnetic flux through a flow of hydrocarbon at varying frequencies.

FIG. 3 illustrates a plot of the measured amplitude of oscillating magnetic flux through multiple separate flows of hydrocarbon, each flow having distinct dielectrics.

FIG. 4 illustrates a plot of the measured amplitude of oscillating flux through multiple water flows, each having distinct concentrations of dissolved ionic compounds.

FIG. 5 illustrates the multiple amplitude curves and centroids for hydrocarbon mixtures containing varying concentrations of potable water.

FIG. 6 illustrates the multiple amplitude curves and centroids for hydrocarbon mixtures containing varying concentrations of a water solution with a constant fixed concentration of dissolved ionic compounds.

FIG. 7 illustrates the plot of centroids from the separate curves illustrated in FIG. 5 and FIG. 6.

FIG. 8 illustrates a plot of measured capacitance of water containing variable concentrations of dissolved ionic compounds at 22 kHz.

FIG. 9 illustrates test data comparing the measured amplitude of 100% kerosene, water and a mixture of kerosene and 5% water.

FIG. 10 illustrates test data comparing 100% kerosene, 100% SAE 30 motor oil and 100% water.

FIG. 11 illustrates test data comparing kerosene and SAE 140.

FIG. 12 illustrates a schematic outline of the some of the components utilized in the invention for creating Metallic Transparencies™, and transmitting and receiving magnetic flux.

FIG. 13 illustrates an embodiment of the invention containing the components for transmitting and receiving magnetic flux, measuring the capacitance and conductivity of the liquid flow.

FIG. 13A illustrates a cross sectional view of the embodiment.

FIG. 14 illustrates another embodiment of the invention containing the components for transmitting and receiving magnetic flux, measuring capacitance and conductivity of the liquid flow.

FIG. 14A illustrates a cross sectional view of the embodiment.

FIG. 15 illustrates another embodiment of the invention wherein the apparatus is housed within the modified tubing but separated from the hydrocarbon production flow.

FIGS. 15A and 15B illustrate cross sectional views of the embodiment of the invention.

FIG. 16 illustrates another embodiment of the invention for transmitting and receiving Oscillating Magnetic Flux.

The above general description and the following detailed description are merely illustrative of the subject invention, and additional modes, advantages, and particulars of this invention will be readily suggested to those skilled in the art without departing from the spirit and scope of the invention.

### DETAILED DESCRIPTION OF THE PREFERRED EMBODIMENTS

To accomplish the purposes of the method and apparatus of this invention, an oscillating magnetic wave is engaged with the liquid. This may include, but is not limited to hydrocarbon and liquid mixtures containing hydrocarbon. The frequency of the oscillating flux is varied across a controlled spectrum. The amplitude of the flux signal received through the hydrocarbon is measured and recorded. Embodiments of the invention can include combining the magnetic flux devices and methods with other devices for measuring the resistivity and capacitance of the liquid flow. It will be appreciated that the liquid is not required to be electrically conductive. However, some components of the liquid, e.g., the solute, solvent, colloidal suspension, etc., should have a magnetic dipole or magnetic moment.

The oscillating magnetic flux may be generated by an A.C. current source or a pulsed direct current electromagnet. Either source of magnetic flux will be termed “Oscillating Magnetic Flux” or “Transmitter Flux.”

As mentioned above, the liquid may include hydrocarbon and hydrocarbon mixtures. Such liquids are termed herein as “hydrocarbon” or “hydrocarbon flow.” The hydrocarbon content can be monitored by the method and apparatus of this invention as it flows through standard ferromagnetic production piping without interruption. In other embodiments, a side stream may be utilized. In yet other embodiments, the method and apparatus can be used in conjunction with batch sampling and laboratory bench testing. In applications which the hydrocarbon contains high concentrations of water, i.e., approaching 100%, it may be desirable to use a water separator.

It wall be appreciated that the invention can be utilized as the hydrocarbon flows through standard ferromagnetic metal piping or similar material that commonly acts as a barrier to the transmission of electromagnetic energy. This may be accomplished by saturating at least one portion of the ferromagnetic pipe or conduit with a magnetic flux, thereby creating a Metallic Transparency™. This Metallic Transparency is preferably created near the source of the Transmitter Flux. A separate Metallic Transparency can be created near the device for receiving the Transmitter Flux.

The method and apparatus of this invention will determine the following parameters of the liquid flow:

The concentration of water.

Salinity of water, i.e., concentration of dissolved ionic compounds or solute within the water.

The dielectric of the hydrocarbon.

It will be appreciated that the invention can be utilized to distinguish or identify other compounds, ions, or elements within a liquid mixture.

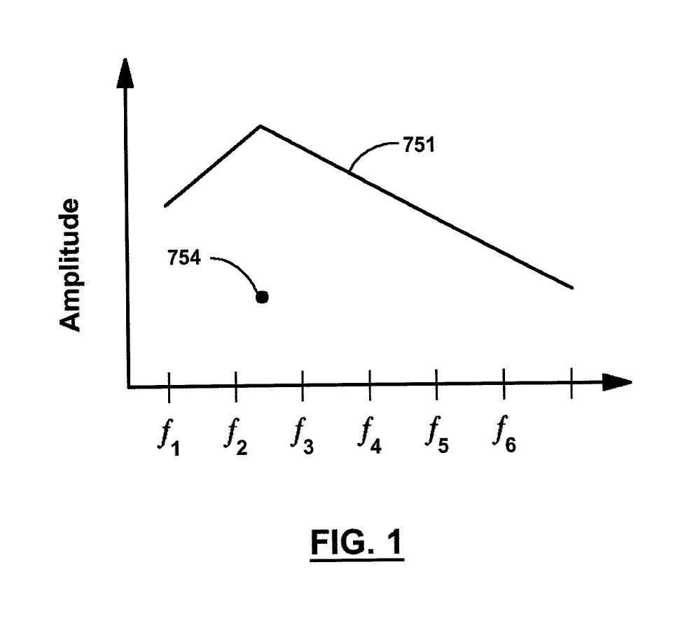

The operation of the invention is described in the following manner. An Oscillating Magnetic Flux is engaged with the liquid flow, e.g., a flow containing a mixture of hydrocarbon and water, at a range of frequencies, preferably 100 to 200 kHz. The Oscillating Magnetic Flux induces an eddy current, which in turn generates an oscillating flux that can be measured by a receiver. It will be appreciated that the receiver be nulled to the Oscillating Magnetic Flux transmitter to minimize the direct transmission of signal from the transmitter to the receiver. The amplitude of the Oscillating Magnetic Flux received through the flow at each frequency is measured and recorded. When the values of amplitude and frequency are plotted for a liquid, e.g., water, a curve similar to that illustrated in FIG. 1 is formed. The curve provides a measure of the dielectric of the liquid.

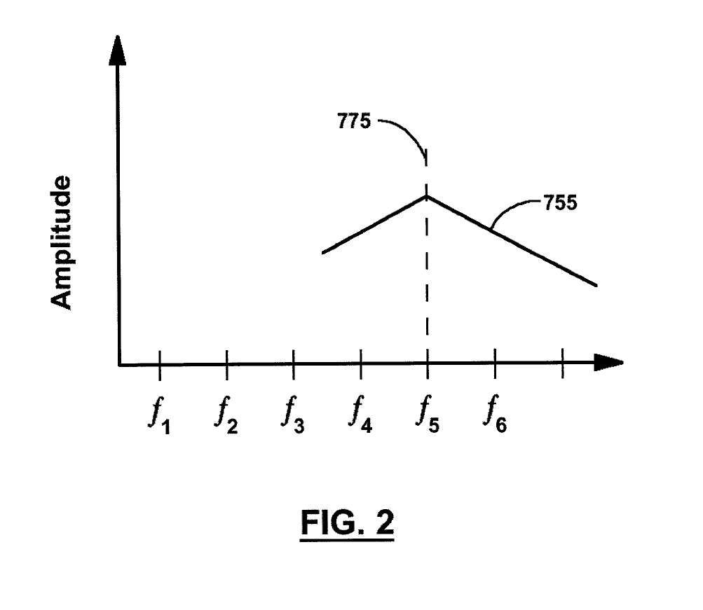

The relationship between the frequency of the Oscillating Magnetic Flux and the measured amplitude of the received flux signal has been found to vary, depending upon the concentration of various components of the mixture, e.g., the respective concentration of water and hydrocarbons within the flow, the concentration of dissolved ionic compounds within the water (hereinafter termed “salinity”) and the density of the hydrocarbon. It has been found that when liquids solely containing hydrocarbon molecules are engaged with the spectrum of Oscillating Magnetic Flux and the corresponding measured amplitudes are recorded, a curve similar to that illustrated in FIG. 2 is formed.

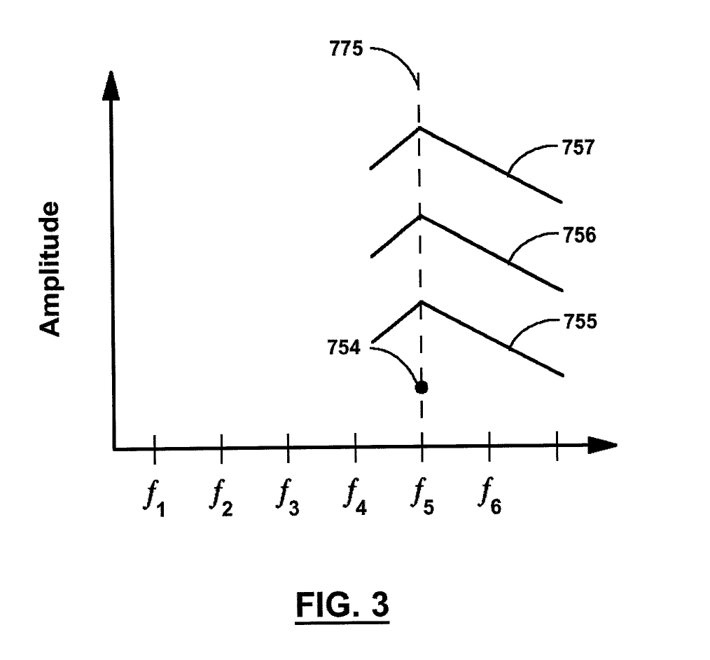

It is well known that a hydrocarbon liquid such as crude oil can contain a mixture of hydrocarbon molecules of significantly differing molecular weight. It has been found that equal volumes of hydrocarbon liquid having differing weight, i.e., differing density, display the curves illustrated in FIG. 3 when the measured amplitude is plotted against the spectrum of frequencies. It is noted that 755, 756, 757 represent differing hydrocarbons wherein 765 is the least dense (most viscous) and 757 is the most dense (least viscous). The plot of the multiple curves illustrates the differing dielectric properties of each hydrocarbon. It is noted that the greatest amplitude for each hydrocarbon occurs when each is engaged with the same frequency of Oscillating Magnetic Flux (f₆).

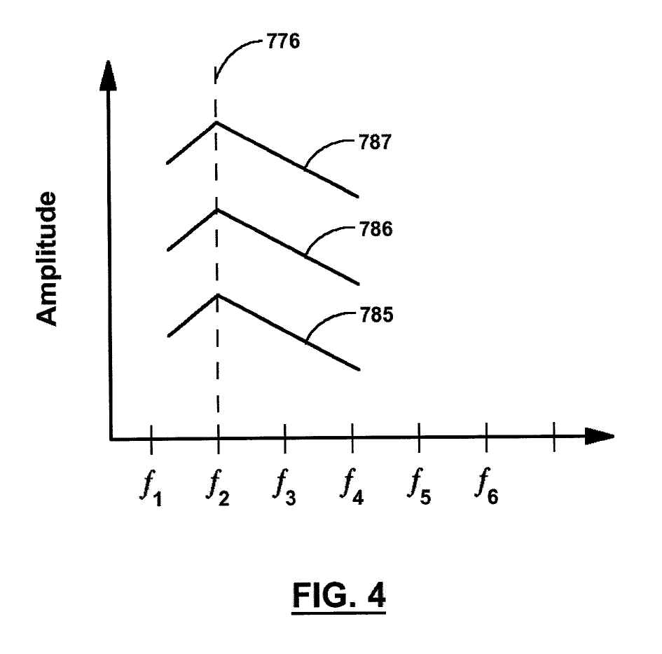

FIG. 4 illustrates the plot of amplitude versus frequency for multiple samples of water, each containing differing concentrations of dissolved ionic compounds. The curve 765 is for potable water. Curve 766 is for water containing a greater concentration of dissolved ionic compounds and 767 represents the recorded amplitude of water containing the highest concentration of dissolved ionic compounds (highest salinity) when engaged with the spectrum of Oscillating Magnetic Flux. It will be appreciated that the peak amplitude increases as the salinity of the water increases. This is at least in part due to the increased electrical conductivity of water having greater salinity. It will, of course, be appreciated that as the concentration of dissolved ionic compounds in water increases, the density of the water solution also increases. This increased salinity facilitates the increased eddy currents that are induced when the liquid is engaged with Oscillating Magnetic Flux. As the strength of the eddy current increases, additional oscillating Magnetic Flux is induced by the eddy current.

It therefore will also be appreciated that as the concentration of water increases in the liquid hydrocarbon flow, the relative salinity of the water must be considered.

The method by which the Transmitter Flux interacts with each water particle is determined by the wavelength “L” of the Transmitter Flux. The interaction is based upon the relation of the water particles' size to the magnetic skin depth “δ” determined by

$$δ = ( \frac{1}{e} ) L$$

$$and$$

$$δ = \frac{1}{\sqrt{σ {μ}_{r} {μ}_{o} f}}$$

where

δ=magnetic skin depth or penetration depth,

σ=conductivity

A=amplitude

f=frequency,

L=wavelength

μᵣ=relative permeability

μₒ=absolute permeability

and “μᵣ” is the permeability of the water particle. It will be appreciated that the permeability of water is unity or 1. When the magnetic flux wavelength equals or is less than the skin depth of the water particle, the fluctuating magnetic flux generates electric fields that generate electric eddy currents in the water particle. These fluctuating eddy currents each in turn generate magnetic flux that is detectable. In addition, the magnetic flux frequency is swept from the highest frequency that would have a wavelength to interact with the smallest size water particles of interest to the largest water slugs in the flow.

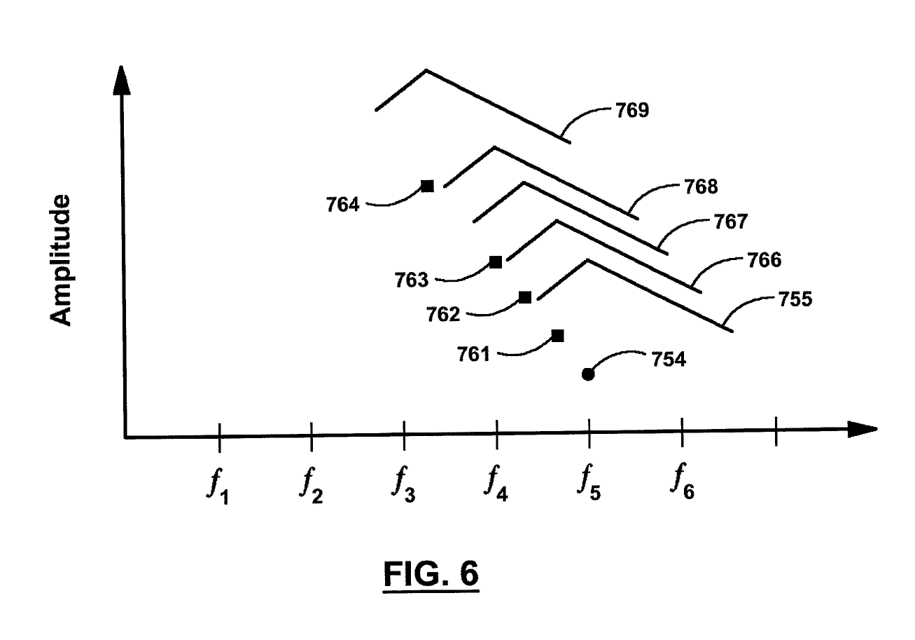

In FIGS. 1 through 6, the relationship of frequencies is:

f₆>f₅>f₄>f₃>f₂>f₁.

The subject invention teaches use of differing methods and apparatus to achieve enhanced measurements of the selected parameters, based upon measurable properties of the liquid flow.

In certain embodiments of the invention, it may be desired to achieve the measurement of capacitance of the liquid by measuring the capacitance of the water contained in the mixture. It has been found that this method is most useful when the water is homogeneously mixed in the hydrocarbon. In other embodiments the parameters may be measured by use of an oscillating magnetic flux transmitted through the liquid. In other embodiments, both measurement of capacitance of the water component and measurement of the resistivity of the hydrocarbon may be used.

As stated above, the parameters of interest are:

The concentration of water,

Salinity of water, i.e., concentration of dissolved ionic compounds or solute within the water,

The dielectric of the hydrocarbon.

The invention can include the following measurements for determining the listed parameters:

1. Electric capacitance measurement of the water within the liquid.

2. Electric capacitance measurement of the resistivity of the hydrocarbon liquid. This measurement can distinguish one highly electrical resistive liquid from another as for example diesel fuel from motor oil.

3. Direct conductivity measurement for salinity determination when larger amounts of saline water are present. The conductivity probe or probes are placed within the flow.

4. Engaging the liquid with magnetic flux oscillating at controlled and variable frequencies that can measure the resistivity of the liquid.

5. A venturi meter also may be used as a measurement of liquid flow rate.

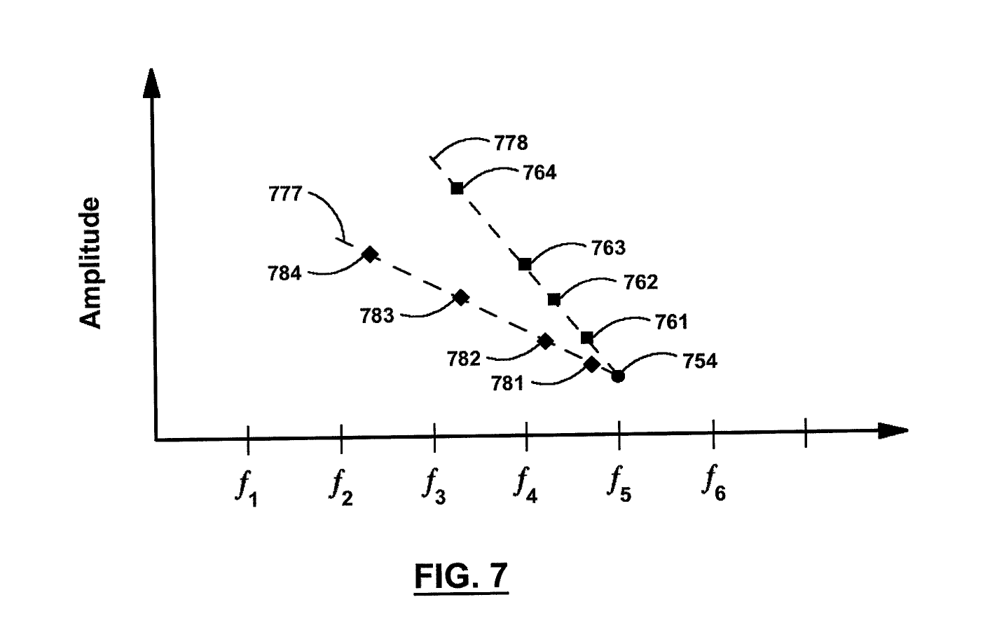

FIG. 7 illustrates that at a given frequency, the measured amplitude of a hydrocarbon water mixture will differ, depending upon the salinity of the water. This distinction increases as the percentage of water within the mixture increases.

In the preferred embodiment of the invention, the concentration of water within the liquid mixture is accomplished by capacitance measurements. Measurements of water concentration of 50 ppm have been achieved. Measurements of capacitance have been found to be useful when the water is homogeneously mixed within the liquid, i.e., where the water or water globules are evenly mixed throughout the liquid, in contrast to relatively large but isolated slugs of water. It has been observed that the dielectric of the mixture varies linearly with the percentage of homogeneously mixed water within a range of approximately zero to thirty or forty percent. At greater concentrations of water, the measured dielectric values increase in a nonlinear manner.

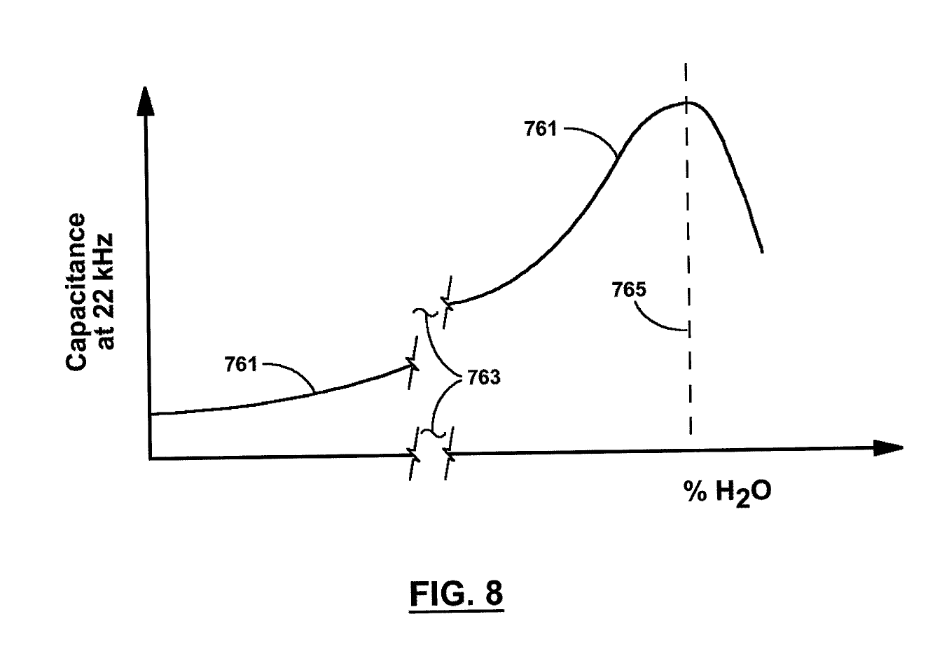

FIG. 8 illustrates the linear relation 761 that exists between measured capacitance and water concentration. This relation becomes nonlinear as the concentration of water increases 763. This is attributed to the creation of larger water particles within the hydrocarbon. The larger diameter water particles facilitate the creation of larger eddy currents and resulting higher measured oscillating magnetic flux. When the water concentration becomes sufficiently large 765 the water particles create a direct path for conducting the electric charge, thereby resulting in the steep drop in the measured capacitance.

In the preferred embodiment, these greater concentrations of water are measured by engaging the liquid with an oscillating magnetic flux transmitted through the liquid. The frequency of the oscillating flux is varied in a controlled manner and the amplitude of the signal received through the liquid is measured and recorded. The preferred embodiment also measures the salinity of water within the mixtures containing these water concentrations. It has been found that salinity of the water also effects the measured dielectric of the mixture.

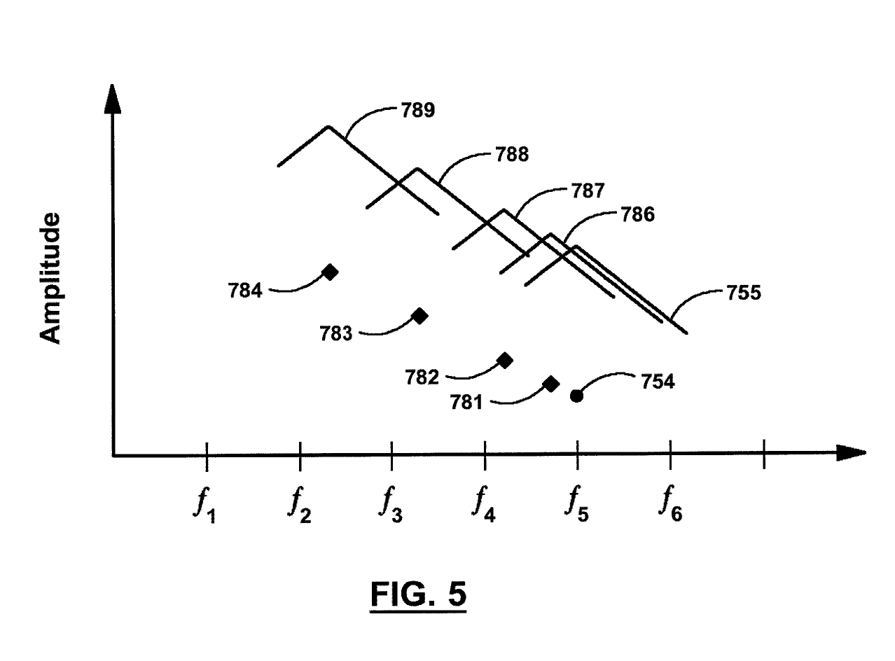

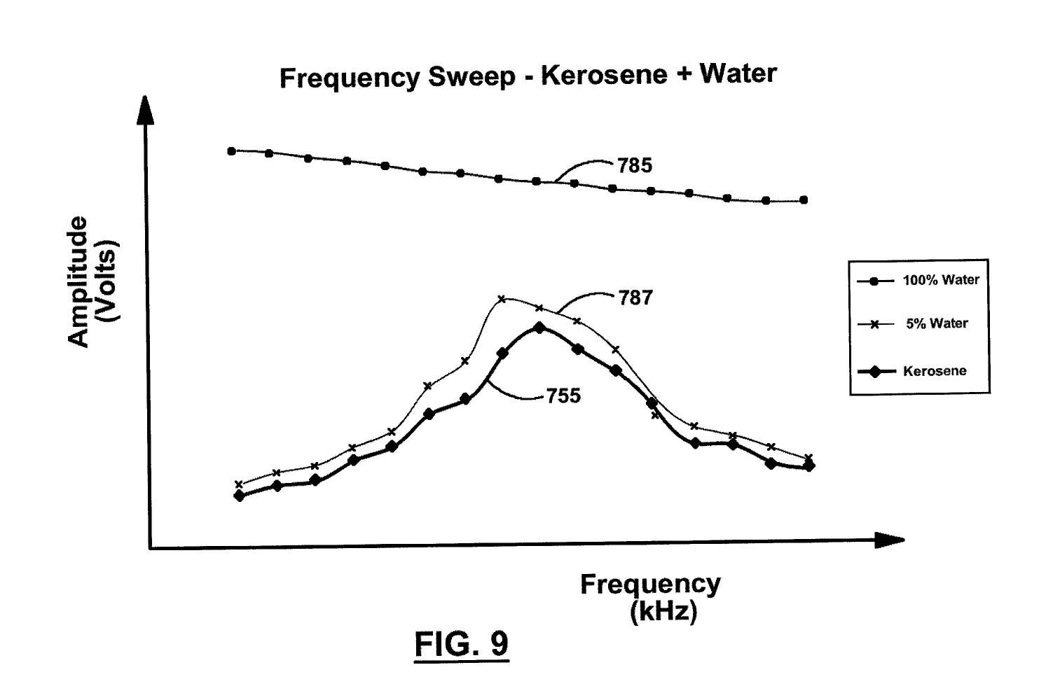

FIG. 9 illustrates measured amplitudes of received oscillating magnetic flux for 100% kerosene 755, kerosene containing 5% water 787, and 100% water 785. It will be appreciated that the peak amplitude for the water kerosene mixture is larger than the peak amplitude of the 100% kerosene. Also, this higher peak occurs at a lower frequency. This is consistent with FIGS. 5,6, and 7. Note also that the measured amplitude of the 100% water 785 is greater than the water kerosene mixture.

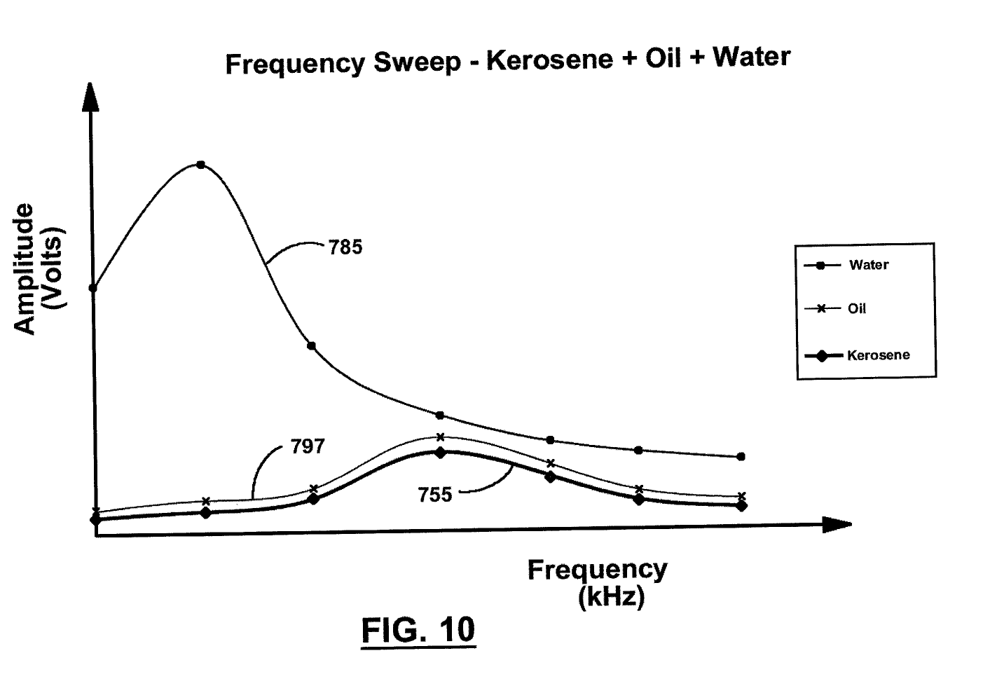

FIG. 10 illustrates measured amplitudes for 100% water 785, 100% SAE motor oil 797 and 100% keroene 755. Note that the peak amplitude for 100% water is greater than the peak amplitudes for the hydrocarbons. Further, the peak amplitude for water is at a lower frequency of oscillating magnetic flux. In addition, the peak amplitude for SAE motor oil, less viscous than the kerosene, is higher than the peek amplitude for kerosene. However, the peak amplitudes for both hydrocarbons are at the same frequency.

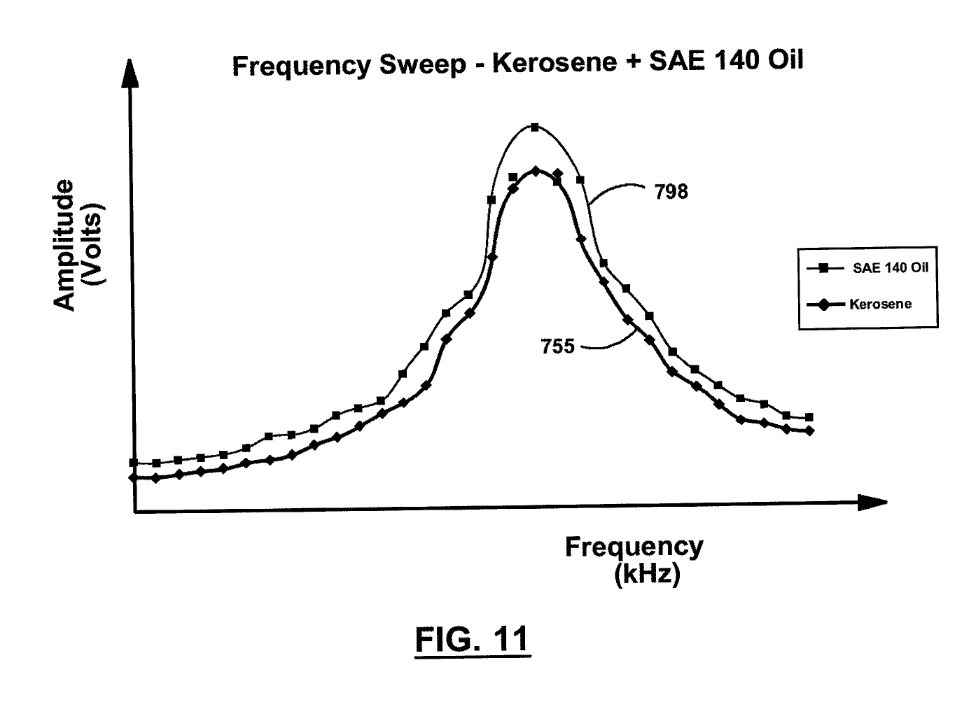

FIG. 11 illustrates measured amplitude for two hydrocarbons having very distinct viscosity's, i.e., 100% kerosene 755 and 140 SAE oil 798. As can be expected, the peak amplitude for both hydrocarbons occurs at the same frequency of oscillating magnetic flux. However, the less viscous hydrocarbon demonstrates a high peak amplitude, confirming that it has a higher dielectric.

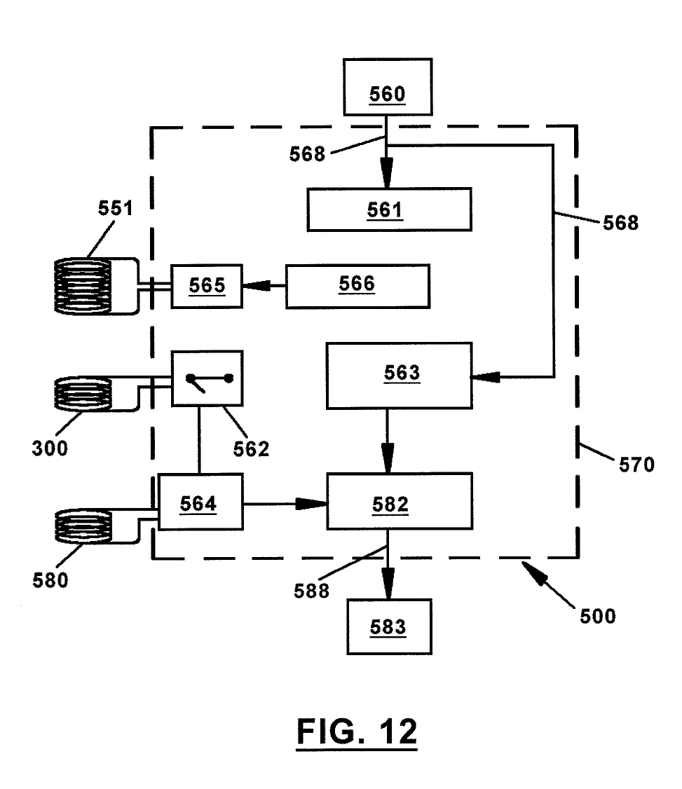

FIG. 12 illustrates the components that may be used to create the Oscillating Magnetic Flux. In the preferred embodiment of the invention, Oscillating Magnetic Flux is used to determine the dielectric of the liquid mixture, specifically when the percentage concentration of water prevents determining the dielectric by measuring electrical capacitance. The Transmitter 300 transmits the Oscillating Magnetic Flux. The Receiver 580 receives the magnetic flux generated by eddy currents within the mixture. The signal is amplified on amplifier 564 and displayed on 583. When the apparatus is used to transmit the Oscillating Magnetic Flux through a ferromagnetic material such as a carbon steel pipe, it is necessary to saturate a portion of the material with magnetic flux. Ferromagnetic metals and other materials that are electrically conductive and magnetically permeable are barriers to the transmission of electromagnetic energy and have been referred to a EM Barrier or Barrier Material. The saturation coil 561 engages the pipe or other material with a constant or low frequency magnetic flux.

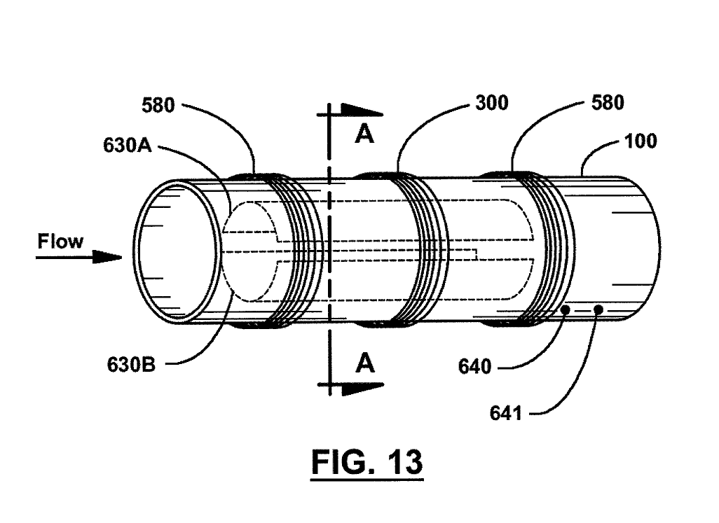

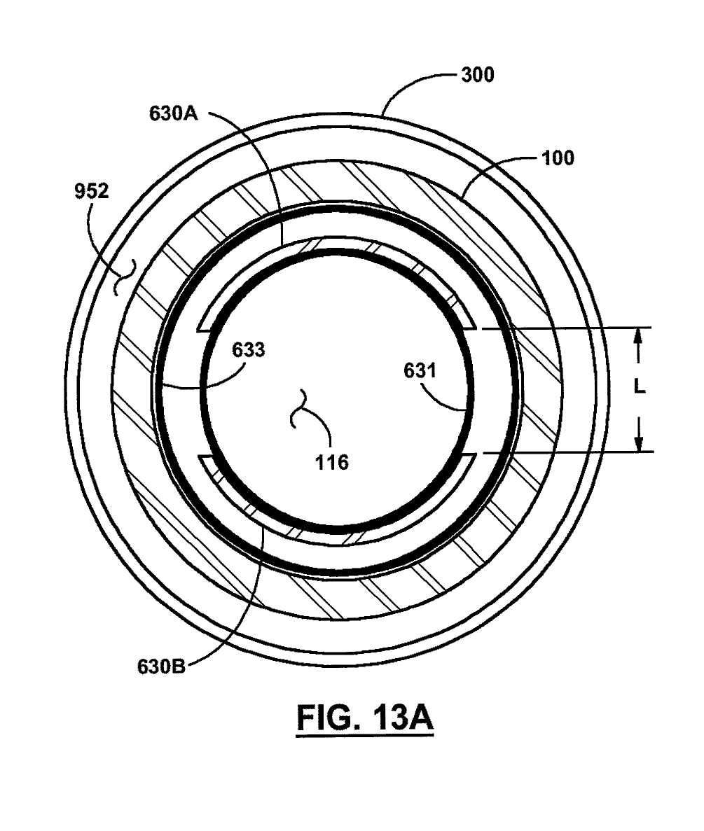

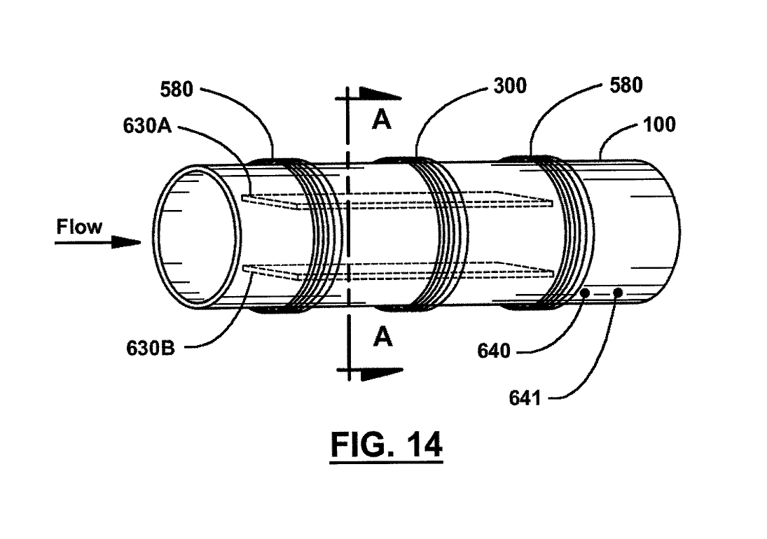

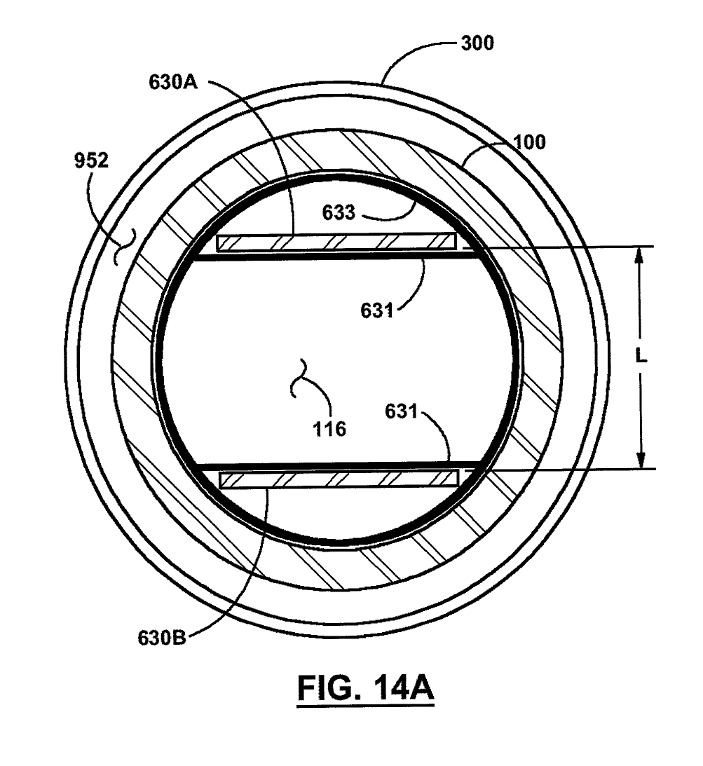

FIGS. 13, 13A, 14 and 14A illustrate preferred embodiments of the invention. The apparatus consists of at least one Transmitter 300 and at least one Receiver 580. The two receivers illustrated are nulled to the Transmitter 300 by being placed equal distances from the Transmitter and each Receiver 580 wound in opposing directions. The Transmitter and Receivers are wound around the conduit 100 carrying the liquid flow. A gap 952 is maintained between the Transmitter or Receiver and the conduit 100. If the conduit consists of a Barrier Material, at least one saturating coil will be required near the Transmitter and Receiver (not shown). The apparatus also contains at least two probes (here 640 and 641) to measure the conductivity of the liquid. The apparatus also contains at least two plates 630A and 630B to measure the electrical capacitance of the liquid flow. The gap L between the plates will be known. It will be appreciated that for mixtures containing sufficiently high concentrations of water or containing non-homogeneously mixed water and other liquids, the electrical capacitance plates may not be operable. It will also be appreciated that it may be advantageous to incorporate insulating or protective devices 631 and 633.

Measurement of liquid hydrocarbon dielectric may be achieved in the preferred embodiment by first taking the flow mixture into a water separator. If the liquid hydrocarbon flowed through in a large enough globules, i.e., non-homogeneous mixture, it could be detected by closely spaced conductivity probes of the 640 and 641.

Salinity measurements can be taken when the mixture contains large concentrations of water as a result of the water globules being large enough to be detectable by the probe spacing of the water conductivity meter. The salinity value may range from potable water at 20-ohm meters to saturated saline water at 0-1 ohm meters. At high saline water levels, the use of oscillating magnetic flux is preferred for measuring the percentage of water. The salinity can be readily measured because of the presence of water conductivity probe can operate.

As the liquid hydrocarbon is reduced as a percentage of the total flow volume, its presence in the flow is harder to detect and measure. Enough flow must be physically separated to be able to perform this measurement. This separator is envisioned as an instrumented vertical pipe with a diameter “d”, located at the test section. Its height would be up to 10 d. A small cut away lip in the flow would force liquid into the pipe where stratification would occur. At the top of this pipe the dielectric of the hydrocarbon could be measured. Secondary measurements could be done at “d” up the pipe to confirm that the stratified hydrocarbon is being re-circulated.

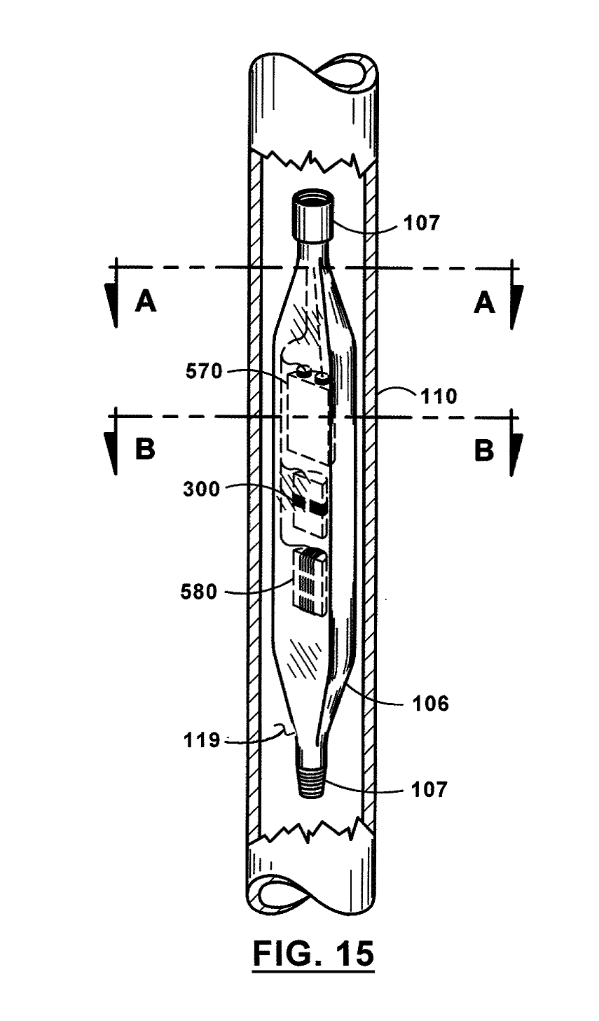

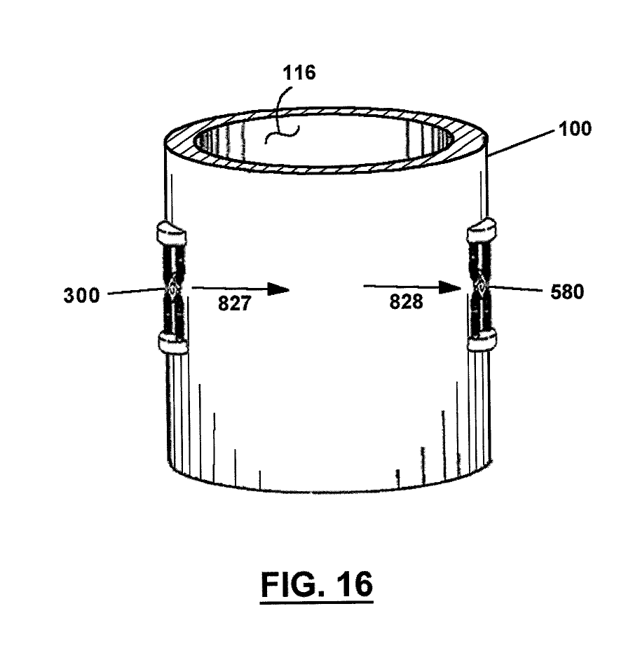

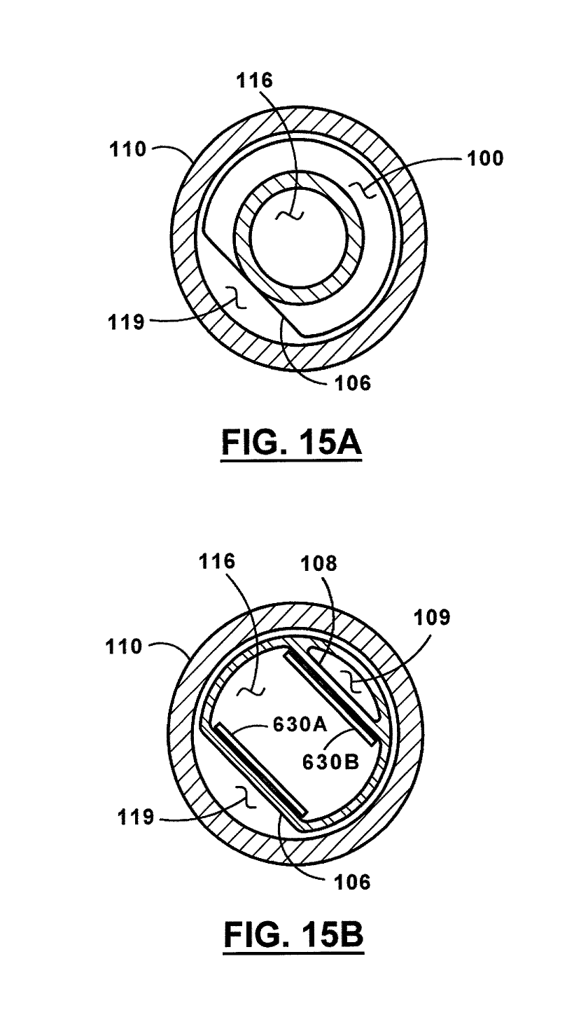

FIGS. 15, 15A and 15B illustrate another embodiment of the invention wherein the components may be placed in a hydrocarbon production well. It will be appreciated that the device will not impede the passage of liquid hydrocarbon. FIG. 16 illustrates still another embodiment wherein one or more bi-static arrays of a Receiver 580 and Transmitter 300 are placed on opposite sides of a conduit.

It will be appreciated to those skilled in the art that modification, changes and substitutions may be made to the invention described above. Accordingly, it is appropriate that the appended claims be construed broadly and in the manner consisting with the spirit and scope of the invention herein.

What I claim is:

1. A method for measuring the concentration of water within a liquid mixture, the concentration of dissolved ionic compounds within the water, and the dielectric of the mixture comprising the steps of:
a. measuring the electrical capacitance of a liquid,
b. measuring the conductivity of the liquid,
c. engaging the liquid with Oscillating Magnetic Flux, means for varying the frequency of the Oscillating Magnetic Flux, and
d. measuring any induced oscillating magnetic flux from within the liquid mixture.

2. The method of claim 1 wherein the liquid comprises a mixture containing hydrocarbon.

3. An apparatus for measuring the concentration of water within a liquid, the concentration of dissolved ionic compounds within the water, and the dielectric of the mixture comprising:
a. means for measuring the electrical capacitance of a liquid,
b. means for measuring the conductivity of the liquid,
c. means for engaging the liquid with Oscillating Magnetic Flux, means for varying the frequency of the Oscillating Magnetic Flux, and
d. means for measuring any induced oscillating magnetic flux from within the liquid mixture.
